(19) United States
(12) Patent Application Publication
(10) Pub. No.: US 2002/0096760 A1
(43) Pub. Date: Jul. 25, 2002

(54) Side access layer for semiconductor chip or stack thereof

(76) Inventors: Gregory Simelgor, Rehovot (IL); Yehuda Rosenblatt, Holon (IL)

Correspondence Address: PENNIE AND EDMONDS, 1155 AVENUE OF THE AMERICAS, NEW YORK, NY, 100362711

(21) Appl. No.: 09/768,804

(22) Filed: Jan. 24, 2001

(51) Int. Cl. H01L 23/34; H01L 21/44; H01L 21/48; H01L 21/50; H01L 23/02

(52) U.S. Cl. 257/723; 257/686; 438/109; 438/107; 438/598; 438/597

(57) ABSTRACT

A method of forming a side access layer on a semiconductor chip, or especially a stack of semiconductor chips, is provided. A region of protective insulating material and one or more conductive pads are formed above a major surface of each chip substrate. Each conductive pad is located at least a certain height above the major surface of the substrate and at least a certain distance away from a side surface of the chip, with the region of protective material generally extending between each conductive pad and the major surface of the substrate. The insulating material thereby protects each conductive pad during subsequent etching of the side surface of each chip substrate. The edge of each conductive pad is then exposed, preferably by planarizing the side surface of the chip or stack. Also, a side interconnect layer may be formed on the side surface of the chip or stack to provide an electrical connection to each conductive pad.

### FIELD OF INVENTION

The present invention relates to the fields of semiconductor devices and integrated circuits, including MicroElectroMechanical system devices. More particularly, the present invention relates to a method of forming a side access layer on a semiconductor chip especially when arranged in a three-dimensional chip stack package.

### BACKGROUND OF THE INVENTION

In integrated circuit technology, a wafer of semiconductor material is grown and then typically diced to separate the wafer into several semiconductor device chips (or dice). In many applications, the semiconductor device chips are integrated circuit (IC) chips that contain a number of active and passive components that function as a complete circuit. However, a semiconductor chip or die may also comprise one or more MicroElectroMechanical system (MEMS) devices. A MEMS device is a micro-device that is generally manufactured using integrated circuit fabrication (or other similar) techniques and is used to sense, control, or actuate on very small scales by combining mechanical, electrical, magnetic, thermal and/or other physical phenomena. These devices typically include a tiny mechanical element such as a sensor, mirror, valve, or gear that is embedded in or deposited on the semiconductor substrate. MEMS devices may also be monolithically integrated with associated driving, control, and/or signal processing microelectronic circuitry.

In many applications, it is desirable to combine several semiconductor chips so that they operate together as an overall system. For example, in two-dimensional electronic modules, semiconductor chips are housed in a carrier and interconnected by wires on a generally planar circuit substrate. In such modules, the semiconductor chips or their carriers typically have conductive leads or pads to facilitate interconnection with the circuit substrate and/or other semiconductor chips. However, two-dimensional chip structures are generally bulky, have a low density of chips for a given space, and have circuit interconnections that often introduce undesirable signal noise and delay due to relatively large chip spacing. Furthermore, for certain MEMS applications—such as the optical switching devices described in commonly assigned U.S. patent application Ser. No. 09/619,014 entitled “Switching Device and Method of Fabricating the Same”, the contents of which are incorporated herein by virtue of this reference—planar chip arrangements are also not suitable.

To alleviate many of these disadvantages, system modules comprising a three-dimensional stack of semiconductor chips have been used. In such a stack, the chips are bonded or secured together, for example using an adhesive material. To provide interconnection circuitry to the chips in the stack, electrical conductors may be used to route electrical connections from the interior portion of a chip to one of its edges. An access layer is then formed on a side surface of the stack corresponding to the chip edges at which the electrical connections are routed. To enable electrical connection between the semiconductor chips in the stack and to circuitry away from the three-dimensional stack module, the side access layer may, for instance, include a conductive metallization interconnect layer.

For example, Beilstein, Jr. et al. in U.S. Pat. No. 5,466,634 disclose an IC chip stack fabrication process in which a thin metallization layer is formed on a side surface of the stack. When stacked, transfer metallization associated with each chip in the stack extends completely to the edge of a selected side surface of the IC chip stack. Insulating material disposed on the surface of each chip, both below and above the transfer metallization, electrically insulates and physically isolates the respective transfer metallization. The selected side surface of the stack undergoes processing with a selective etch to remove the edge portions of the IC chips, but not the transfer metallization or the insulating material around it. A further insulating layer is thereafter deposited on the side surface. The insulating material is subsequently removed to expose the ends of the transfer metallization. The side metallization layer is then deposited on the side of the stack and forms T-connects that electrically couple the side metallization layer to the transfer metallizations of the IC chips.

However, existing methods of forming side access and interconnection layers for IC or semiconductor chip stacks typically require careful alignment of the chips when bonding or laminating the chips to one another. They also generally involve a number of steps, at least some of which are often relatively complex and expensive processes. In addition, conventional side metallization processes, such as that disclosed by Beilstein, Jr. et al., tend to be unsuitable for stacks of semiconductor MEMS chips in which polysilicon (and not some form of metallization) is used as a conductor. As a result, there is a need for a method of forming a side interconnection layer for a stack of semiconductor chips that does not require careful chip alignment and is relatively simple, inexpensive, and suitable for semiconductor chips (such as MEMS devices) that use polysilicon as a conductive material.

### SUMMARY OF THE INVENTION

The present invention provides, in one aspect, a method of forming a side access layer on a semiconductor chip in which a region of protective insulating material and one or more conductive pads are formed above a major surface of a chip substrate. (The semiconductor chip may be an integrated circuit or a MEMS chip having one or more MEMS devices integrated with microelectronic circuitry.) Each conductive pad is located at least a certain height above the major surface of the substrate and at least a certain distance away from a side surface of the chip, and the region of protective material generally extends between each conductive pad and the major surface of the substrate. When the side surface the chip substrate is etched to remove a portion of the chip substrate, the protective insulating material protects each conductive pad during the etching of the chip substrate. An edge of each conductive pad is then exposed, preferably by planarizing, e.g., polishing, the side surface of the chip to expose an edge of each conductive pad. Prior to planarizing the side surface of the chip, a second insulating material, which is preferably adhesive, may be deposited on the side surface of the chip. A metallized side interconnect layer may be formed on the side surface of the chip to provide an electrical connection to each conductive pad. Alternatively, the exposed edge of each conductive pad may be wired bonded to provide electrical connections off of the chip.

In another aspect of the present invention, a side access layer is formed on a stack of semiconductor chips. As above, for each chip to be included in the stack, a region of protective insulating material and one or more conductive pads are formed above a major surface of a substrate of the chip, and each of the conductive pads is located at least a certain height above the major surface of the chip substrate and at least a certain distance away from a side surface of the chip. The region of protective material generally extends between each conductive pad and the major surface of the chip's substrate. The chips are secured in a stack, e.g., by bonding, with the side surfaces of each of the chips being generally aligned with one another to provide a side stack surface. The substrates of the chips at the side stack surface are etched to remove a portion of each chip substrate, and the protective insulating material protects each conductive pad during the etching step. An edge of the conductive pads on each chip is then exposed, preferably by planarizing (e.g., polishing) the side stack surface. Prior to planarizing the side stack surface, a second insulating material may be deposited on the side stack surface of the chip, and a side interconnect metallization layer may then be formed on the side stack surface to provide an electrical connection to the conductive pads on each chip.

On a semiconductor chip, the region of protective material preferably also generally extends between each conductive pad and the side surface of the chip, and more preferably it surrounds each conductive pad. The region of protective material may also extend along the entire major surface of the substrate, and a top surface of the region of protective material may be planarized to facilitate stacking of the chip with another chip The chip substrate may comprise silicon, the one or more conductive pads may be formed of polysilicon material, and the protective insulating material may be silicon oxide or silicon nitride. Etching the chip substrate may comprise chemically etching the chip substrate, e.g. using KOH or TMAH as an etchant.

Securing the chips in a stack may comprises bonding each chip to an adjacent chip, preferably by applying a layer of adhesive material between the substrate of said chip and the layer of protective insulating material of the adjacent chip. Preferably, the chips in the stack are secured so that the side surfaces of each of the chips in the stack are aligned, and where the largest misalignment distance between the side surfaces of any two chips in the stack represents a maximum misalignment. The maximum misalignment is preferably less than the minimum distance between each of the conductive pads on a chip and the side surface of that chip, and each of the conductive pads on each chip is preferably located the same distance away from the side surface of that chip. Also, after securing the chips in a stack and before etching the substrates of the chips, the side stack surface may be initially planarized, wherein after the initial planarizing, for each chip, each of the conductive pads remains at least some distance away from the side surface of that chip.

### BRIEF DESCRIPTION OF THE DRAWINGS

The objects and advantages of the present invention will be better understood and more readily apparent when considered in conjunction with the following detailed description and accompanying drawings which illustrate, by way of example, preferred embodiments of the invention and in which:

FIG. 1 is a top view of an edge portion of a semiconductor chip suitable for having a side interconnect layer formed in accordance with a preferred embodiment of the present invention;

FIG. 2 is a cross-sectional view of the chip along the line 2-2 in FIG. 1;

FIG. 3 is a cross-sectional view of an edge portion of a stack of three chips as shown in FIGS. 1 and 2;

FIG. 4 is a cross-sectional view of the stack of FIG. 3 after the side of the stack has been planarized in accordance with a preferred embodiment;

FIG. 5 is a cross-sectional view of the stack of FIG. 4 after the side of the stack has undergone a selective etch in accordance with a preferred embodiment;

FIG. 6 is a cross-sectional view of the stack of FIG. 5 after an insulating material is deposited to cover the stack side surface in accordance with a preferred embodiment;

FIG. 7 is a cross-sectional view of the stack of FIG. 6 after the side surface of the stack has undergone another planarization process in accordance with a preferred embodiment;

FIG. 8 is a cross-sectional view of the stack of FIG. 7 with a side interconnect formed on side surface of the stack in accordance with a preferred embodiment; and

FIG. 9 is an illustrative embodiment of a side interconnect formed on a stack side surface in accordance with in accordance with a preferred embodiment of the present invention.

### DETAILED DESCRIPTION OF PREFERRED EMBODIMENTS

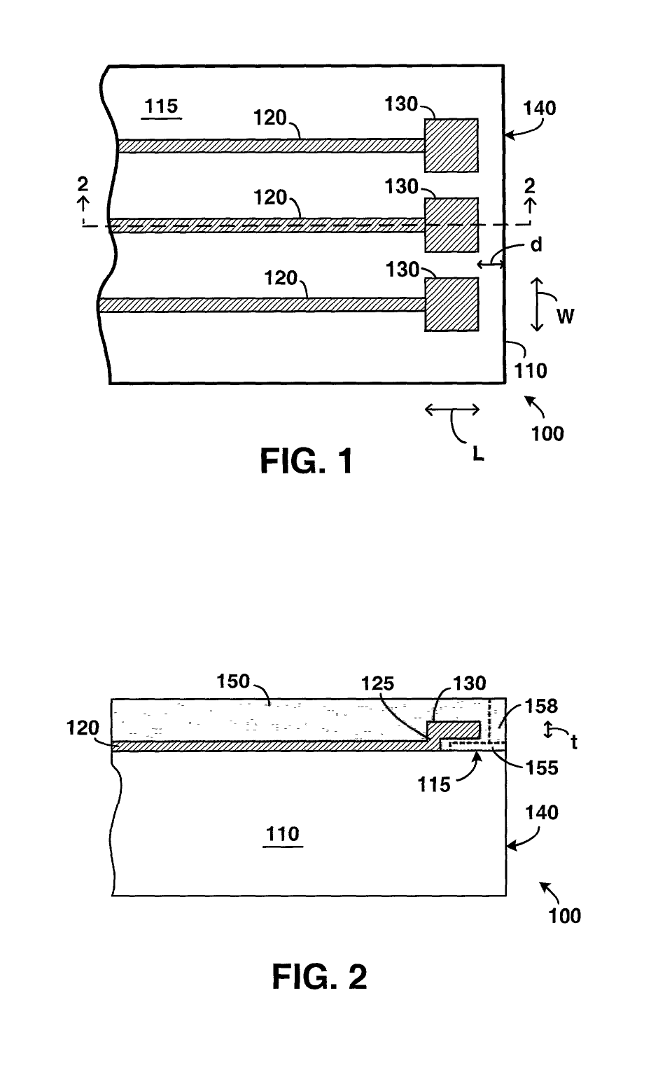

FIG. 1 is a top view of a portion of a semiconductor chip 100 suitable for having a side access layer formed in accordance with the present invention, for example, after inclusion in a semiconductor chip stack. Semiconductor chip 100 is a wafer or, more commonly, a diced segment of a wafer that comprises one or more semiconductor devices. Chip 100 may be an integrated circuit or a MEMS device having associated driving, control, and/or signal processing microelectronic circuitry. More generally, chip 100 may comprise any discrete device with microelectronics for which it is desirable to form a multi-chip stack and/or provide signal connection access from the side or edge of the chip.

Generally, chip 100 may be fabricated using conventional integrated circuit, micro-machining, meso-machining, and/or macro-machining techniques. Preferably, micro-machining technology (i.e., deposition, lithography, and etching techniques) are used to manufacture chip 100. It will be appreciated that, depending on the configuration and application of chip 100, the specific fabrication processes and materials used will vary. For example, chip 100 may be a MEMS device formed using either bulk or surface micro-machining technology. (As used herein, the term MicroElectroMechanical or MEMS device is intended to embrace devices that are physically small and have at least one component produced using micro-machining or other micro-fabrication techniques. Exemplary MEMS devices and process are described in commonly assigned U.S. patent application Ser. No. 09/619,013, entitled “Microelectromechanical Device with Moving Element”, the contents of which are incorporated herein by virtue of this reference. Furthermore, more detailed discussions of silicon processing for MEMS devices are given by Chertkow et al., “Opportunities and Limitations of Existing MicroFabrication Methods for Microelectromechanical Devices”, Proc. 25th Israel Conf. on Mechanical Engineering, Technion City, Haifa, Israel, p. 431 (May 1994) and by Petersen, “Silicon as a Mechanical Material”, Proceedings of the IEEE, vol. 70, no. 5 (May 1982), the contents of each being incorporated herein by virtue of this reference.)

With bulk micro-machining techniques, microstructures are formed by etching away the bulk of the substrate wafer to produce the desired structure. On the other hand, surface micro-machining techniques build up the structure in layers of thin films on the surface of a suitable substrate. Typically, films of a structural material and a sacrificial material are deposited and etched in sequence. Once the desired structure has been formed, the sacrificial material is etched away to release the structure. In general, fabrication of the integrated microelectronics for a MEMS chip may be performed simultaneously with, before, or after, structural surface machining steps. In addition, due to its mechanical properties and compatibility with modern fabrication processes, polysilicon, i.e., polycrystalline silicon, is often used as a structural material for MEMS devices. In particular, polysilicon is strong, flexible, fatigue-resistant, and highly-compatible with integrated circuit fabrication techniques. Polysilicon is often used as a conductive connection line in MEMS semiconductor chips since the formation of intermediate (i.e., below the top deposition layer) metallization layers in MEMS devices is generally expensive and complex. Polysilicon may also be used as a conductor in other types of semiconductor chips such as ICs.

Referring to FIG. 1, chip 100 is formed in and/or on a substrate 110. Generally, the materials, dimensions, thickness, and surface preparation of substrate 110 may vary, and these criteria typically depend on the purpose and operation of chip 100. For many types of chips 100, including MEMS devices, substrate 110 is formed of silicon, however other materials such as gallium arsenide may also be used. FIG. 1 shows a portion of chip 100 in which a number of conductive lines 120, each connected to a conductive pad 130, are provided above a major surface 115 of substrate 110 near an edge or side surface 140 of the substrate. The conductive pads 130 are formed so that each is located at least a certain distance, d, from the edge or side surface 140 of chip 100. Preferably all of the conductive pads 130 are located the same distance d from the side surface 140. The distance d is used to accommodate misalignment in stacked chips, as explained below, and may also serve to ensure that pads 130 are not affected or damaged during dicing of the original wafer. In addition, each conductive pad 130 has a width W and a length L, and in a preferred embodiment the dimensions W and L are the same for each pad 130. The length of the distance d is preferably less than the smallest length of a pad 130 on chip 100.

Conductive lines 120 and conductive pads 130 may be formed of a conductive metal, however, where semiconductor chip 100 is a MEMS device, lines 120 and pads 130 are preferably formed of polysilicon. In general, conductive pads 130 are similar to conventional chip bonding pads that are commonly used to electrically connect a semiconductor chip with a wire, and therefore pads 130 (and conductive lines 120) may be manufactured using standard fabrication techniques.

FIG. 2 shows a cross-sectional view of chip 100 along the line 2-2 in FIG. 1. As illustrated in FIG. 2, although each conductive interconnect 120 may run along the surface 115 of substrate 110 (or, alternatively, within substrate 110), conductive pads 130 are raised above substrate surface 115. In this manner, each conductive pad is located at least a certain height above surface 115 of the substrate. Thus, if necessary, a conductive pad 130 may be connected to a conductive line 120 by way of a vertical conductive line portion 125 which may be a via or the like.

As illustrated in FIG. 1, conductive pads 130 preferably have a width, W, that is wider than conductive lines 120. In addition, conductive pads 130 are preferably relatively thick and, as a result, may also be thicker than conductive lines 120, as illustrated in FIG. 2. Alternatively, however, conductive pads 130 may be of the same dimension as conductive lines 120, so that pads 130 are simply end portion extensions of those lines. In one preferred embodiment, however, conductive pads 130 have a width of about 50 μm and a thickness of at least 1 μm. More preferably, in MEMS applications, in which conductive pads 130 are formed of polysilicon, pads 130 may have an even greater thickness of up to 10 μm or more.

In an alternative embodiment (not shown), multiple conductive layers may be formed above substrate 110, so that, for example, conductive pads 130 may be formed on top of one another (i.e., in different conductive layers) above substrate surface 115. In this embodiment, conductive lines 120 may run within one or more of the conductive layers and vias may be used to connect different conductive layers.

Referring to FIG. 2, an insulating protective material 150, which may be an oxide (such as silicon dioxide) or a nitride (such as silicon nitride) is deposited above at least a part of substrate surface 115, so that material 150 can protect pads 130 during a subsequent etching step, described below. To do so, protective material 150 is provided in a protective region 155 that generally extends between each conductive pad 130 and surface 115, i.e., underneath conductive pads 130 that are formed above substrate surface 115 as indicated above. In addition, it is preferred that protective material 150 also be provided in the region 158 that is generally between each conductive pad 130 and edge 140 of chip 100, as illustrated in FIG. 2.

Moreover, in the illustrated embodiment of FIG. 2, protective material 150 is deposited along the entire surface 115 of substrate 110 and surrounds conductive pads 130 on all sides. In this embodiment, protective material 150 may be deposited in two or more separate steps. In an initial deposition step, prior to the formation of conductive pads 130, material 150 is deposited to provide a layer of protective material that will lie underneath pads 130 (once those pads are formed). In a subsequent deposition step, after pads 130 are formed, protective material is provided both adjacent (along edge 140) and above each conductive pad 130. More generally, as described above, lines 120, pads 130, protective material 150, and any other material layers may be formed using deposition, patterning, and etching processes well-known to those skilled in the art. Where chip 100 comprises a MEMS device having structural elements, these may be formed either above or below protective material layer 150.

In one embodiment, protective material 150 preferably extends to cover the entire area between each conductive pad 130 and surface 115 and also the entire area adjacent between each conductive pad 130 and edge 140. In a more preferred embodiment, as shown in FIG. 2, protective material 150 is further deposited along the entire surface 115 of substrate 110 so that material 150 surrounds conductive pads 130 and also covers conductive lines 120 (if they are formed above the substrate surface 115). In this embodiment, the top surface of the protective material layer 150 may be planarized after deposition (e.g., using polishing techniques) to facilitate the stacking of another chip onto that layer. However, to protect pads 130 during the etching step described below, material 150 generally need only be deposited in a protective region 155, and, for instance, another type of material (e.g., an adhesive material) could alternatively be deposited outside region 155. In such an alternative embodiment, material 150 may first be formed within protective region 155 and subsequently conductive pads 130 and other material layers may be formed.

Generally, chip 100 includes micro-electronic circuitry (not shown), and each conductive line 120 and associated conductive pad 130 acts as an electrical node in that circuitry. Each conductive pad 130 (in a manner described below) enables an off-chip connection for a signal used in the operation of chip 100, such as an input signal, output signal, positive or negative supply, or ground reference. As a simple example, a chip may have conductive pads 130 for receiving a positive supply voltage signal, a ground reference voltage signal, and an input control voltage signal. In general, however, chip 100 may have any number of signals that require a conductive pad to provide an off-chip connection. Also, conductive pads 130 may be located near more than one edge of chip 100 to provide additional connections (in that case, the fabrication process described below is applied to produce a side interconnect layer at each edge of chip 100 near which conductive pads 130 are located).

As described above, it is often desirable to arrange multiple semiconductor chips 100 in a stack to have a higher density of chips in a given space and to reduce delays and noise in circuit interconnections between chips. In addition, in MEMS device chips structural elements (such as moveable mirrors or valves) may be formed above the chip's substrate surface, and the chip may require accurate orientation with respect to other system components (such as an optical fiber). For these chips, it may additionally or alternatively be difficult to provide accessible signal connections above the same substrate surface over which the structural elements are formed. In these and other cases, the formation of a side interconnect layer in accordance with the present invention helps remedy these problems. Although the remainder of this description relates principally to the formation of a side interconnect layer for a stack of semiconductor chips, it will be appreciated that the formation of a side interconnect layer may also be desirable, in some circumstances, for a single stand-alone chip.

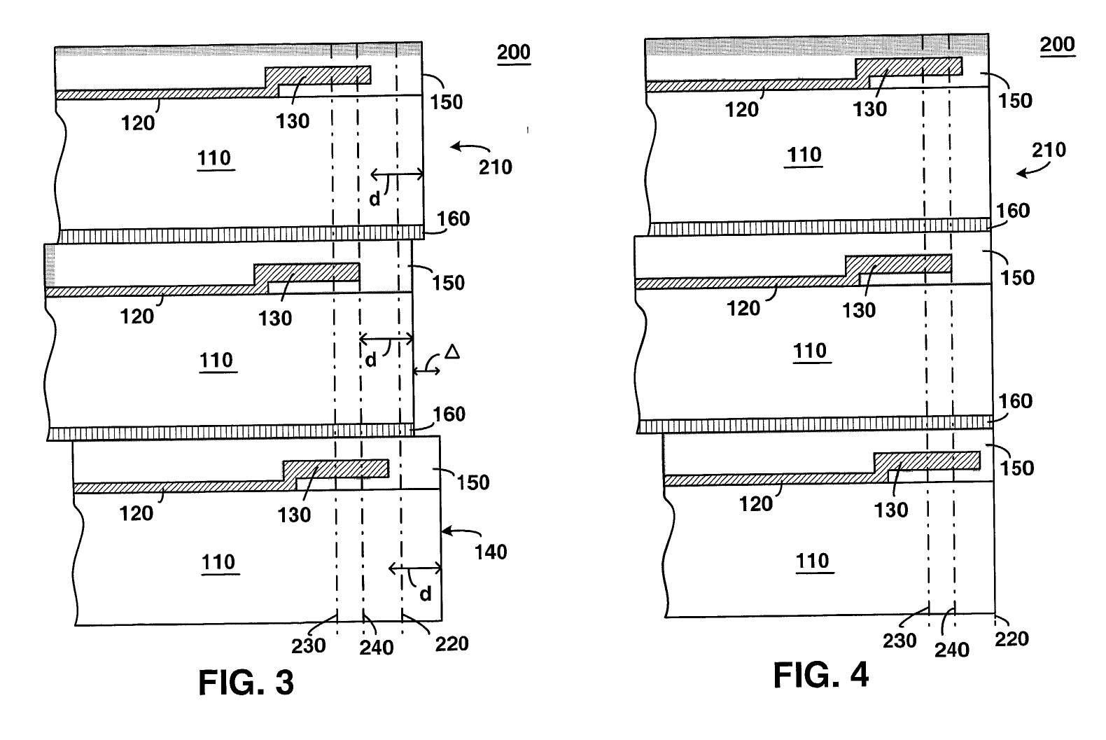

Referring next to FIG. 3, a cross-sectional view of an edge portion of a stack 200 having three semiconductor chips, as described above, is shown. The semiconductor chips are bonded, laminated or otherwise secured together to form stack 200 with the edge 140 of each chip positioned along the side 210 of stack 200. To secure the chips together, anodic, fusion, eutectic, adhesive, or other bonding techniques may be used. In the illustrated embodiment of FIG. 3, thin layers of adhesive material 160 are employed to adhere the substrate 110 of one chip to the layer of protective material 150 above the substrate of an adjacent chip. The adhesive material 160 is preferably non-conductive and may, for instance, be epoxy glue or the like. An end cap (not shown in FIG. 3) may optionally be used to cover the layer of protective material 150 for the chip at the end of the stack that has that layer exposed (the uppermost chip in FIG. 3), although this increases the size of the stack module to some extent. It will be appreciated that although three chips are shown in stack 200, the stack may in general have any number of chips.

In forming stack 200 by securing or bonding, the chips, advantageously, need not be aligned with a high degree of accuracy. As a result, the edges of the chips forming the side 210 of stack 200 may be offset from one another, as shown in FIG. 3. The maximum possible misalignment Δ between any two chips in stack 200 is less than the distance d on each the chip, i.e., the distance that conductive pad 130 is offset from the edge 140 of chip 100. (Although, not preferred, if the distance d varies for the chips within the stack, the misalignment tolerance should be less than the smallest distance d on any chip in stack 200.) Thus, for example, if the maximum possible misalignment between any two chips after using a particular stacking process (and considering other possible causes of misalignment such as errors or inconsistencies after the dicing of the chips) is Δ, each chip 100 may be designed so that the pad offset distance d is larger than Δ, such as d=3Δ. In one embodiment of the present invention, the maximum misalignment Δ may be in the range of 10-40 μm, however it will be appreciated that larger misalignments may also be tolerated and accommodated. Generally (or at least probabilistically), the more chips that are included in stack 200, the greater the maximum possible misalignment between any two chips in the stack becomes.

Once the chips have been initially secured together to form stack 200, side 210 of stack 200 preferably undergoes a polishing, grinding or other similar process step to remove any adhesive overflow (e.g., from layers 160) that occurred during the initial bonding step and to smooth or planarize side 210. Preferably, chemical mechanical planarization (CMP) is performed on the surface 210. Chemical mechanical planarization is a polishing process that uses a chemical slurry formulation and mechanical polishing process to remove unwanted conductive or dielectric materials to achieve a highly flat and smooth surface. As is well known in the art, slurry is a liquid carrier with a suspended abrasive component, e.g., aluminum oxide or silica, that acts as a polishing, grinding, or lapping compound.

FIG. 4 shows the same cross-section of stack 200 after side 210 has undergone a polishing, grinding, or other similar planarization step as described above. As illustrated in FIGS. 3 and 4, side 210 is planarized to a level marked by the broken line 220 in FIG. 3. (The significance of the additional levels indicated by the broken lines 230 and 240 in FIG. 3 will be described below.) As shown in FIGS. 3 and 4, the side surface level 220 is selected to ensure that after the above-described planarization step, conductive pads 120 will remain protected by material 150 (during the subsequent etching step described below). Thus, after this planarization step, pads 130 are still offset from the planarized side surface 210, although the amount of this offset varies from chip to chip depending on the degree of misalignment during stacking.

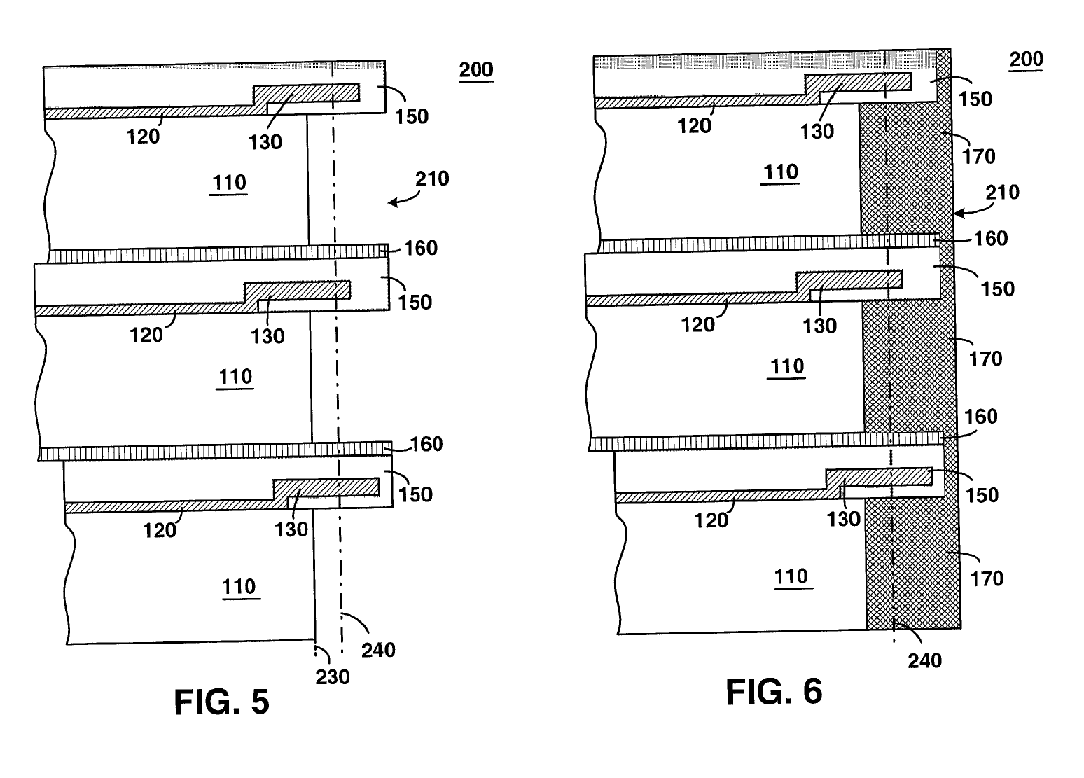

The side surface 210 next undergoes a selective etch process step. As shown in the cross-sectional view of FIG. 5, the edge portion of substrate 110 of each chip in stack 200 is etched to the side surface level marked by the broken line 230, which is also in FIGS. 3 and 4. As illustrated, the side surface etching level 230 preferably intersects each of the conductive pads 130 of the chips in stack 200. During this etching step, material 150 in region 155 (FIG. 2) serves to protect pads 130. Thus, protective region 155 generally extends underneath pads 130 past the farthest possible location of etching level 230 in chip 100, given the maximum possible misalignment Δ.

Although a chemical etch is preferably performed, other etching techniques may alternatively be used to etch into substrates 110. In the case of chemical etching, protective material 150 has different chemical properties from substrate 110, so that the etchant used only has a small etch rate (or etching effect), if any, on the high selectivity protective material. In this manner, material 150 serves to protect conductive pads 130 during the etching process, which is especially desirable where the conductive pad is not etch resistant. (The etchant also preferably has little effect on adhesive material 160.) The etchant will generally depend on the type of substrate material. For example, where chip substrates 110 are formed of silicon, KOH (potassium hydroxide) or TMAH (tetramethylammonium hydroxide) may be used as a wet etchant. The main advantages of a KOH etchant are its relatively high etch rate on silicon, a relatively small etch rate on oxides, such as silicon dioxide, and virtually no etch rate on nitrides, such as silicon nitride. However, other types of etchants such as EDP (ethylene diamine pyrocatechol) or HNA (acetic acid) may also be used on silicon and other substrates. In all cases, the use of protective material 150 to ensure that the etchant does not damage the conductive pads 130 is of particular importance, especially, for example, where chip substrates 110 are formed of silicon and conductive pads 130 (and conductive lines 120) are formed of polysilicon.

After the selective etching of chip substrates 110, stack side surface 210 is preferably covered with a non-conductive or insulating material 170 as shown in the cross-sectional view of FIG. 6. Material 170 may be epoxy and can also be the same material as that used in adhesive layers 160. Where material 170 is adhesive, which is preferred, it provides additional bonding strength for securing together the chips in stack 200. However where the initial bonding (e.g., using adhesive layers 160) is secure enough, any suitable non-conductive or insulating material may be used. Deposition of insulating material 170 may be accomplished, for example, through a liquid spin coating process. In the preferred embodiment illustrated, the deposition of insulating material 170 upon side surface 210 occurs to at least fill the etched edge regions of the chip substrates 110 to the level marked by the broken line 240.

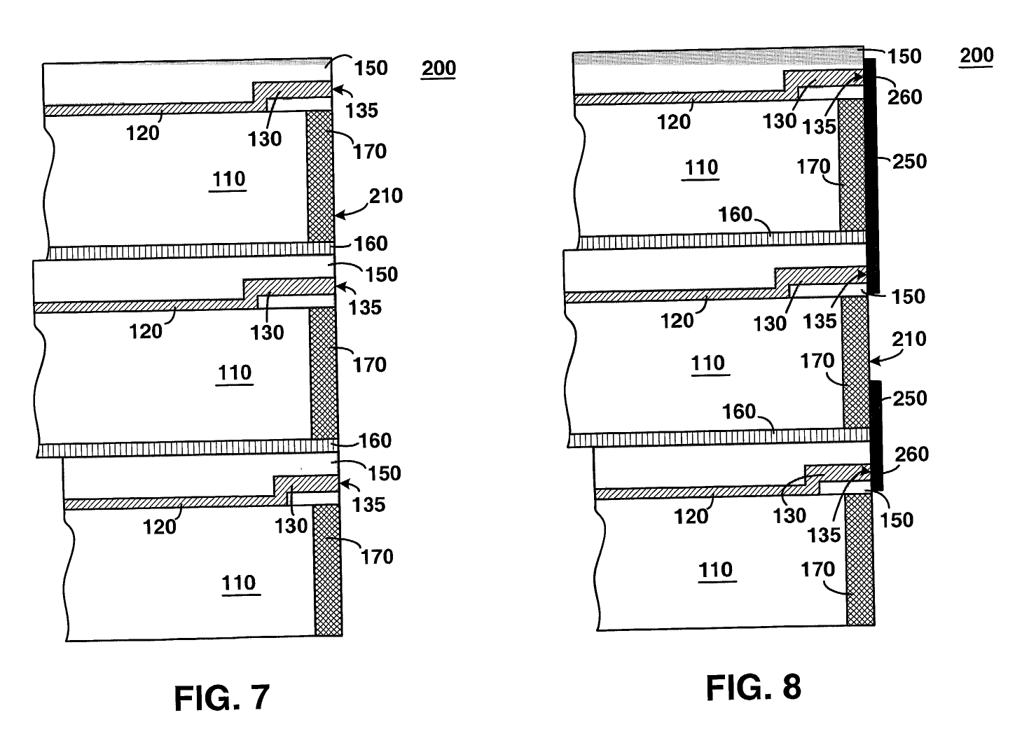

FIG. 7 shows the cross-section of stack 200 and its side surface 210 after another planarization process step is preferably performed on that surface. This planarization step serves to provide a highly flat and smooth access layer or platform—the surface of which principally comprises material 170—on which a side interconnect layer may be subsequently formed (see FIG. 8). In a preferred embodiment, to planarize surface 210 as shown in FIG. 7, a polishing step (e.g., chemical mechanical planarization) is first carried out and then this polishing step is followed by a lapping step. The planarization of stack surface 210 occurs at the level marked by the broken line 240 in FIGS. 3-6. As shown, when stack side surface 210 is planarized at level 240, an edge 135 of each conductive pad 130 is exposed along the surface 210.

FIG. 8 provides a cross-sectional view of stack 200 with a side interconnect layer 250 formed upon the side surface 210 of stack 200. As indicated above, the planarization step carried out prior to deposition of side interconnect layer 250 provides a highly flat and smooth access layer or base for interconnect 250 and thereby helps ensure that there are no undesirable discontinuities in interconnect layer 250. Side interconnect layer 250 forms an electrical connection 260 with the exposed edge 135 of conductive pads 130. Side interconnect layer 250 may then connect a conductive pad on a particular semiconductor chip to a conductive pad on another chip and/or to an off-stack module. Side interconnect layer 250 is preferably a metallization layer, and in one preferred embodiment side interconnect layer comprises a Ti/Al (titanium-aluminum) metallization having a 0.05 μm layer of Ti and 2 μm layer of Al. However, side interconnect layer 250 may also be formed of other conductive materials, such as conductive adhesive materials (for example, epoxy silver). Side interconnect layer 250 may be deposited using any desired technique including liftoff, lithography and etch, or silk printing of a conductive adhesive. If desired, side interconnect 250 may also be formed with multiple layers (not shown) that connect using vias.

In an alternative embodiment to that illustrated in FIGS. 6-8, after chip substrates 110 are selectively etched, as shown in FIG. 5, edges 135 of conductive pads 130 may be exposed using a polishing, grinding, lapping or other similar process step. Conductive wires (not shown) may then be bonded to the exposed conductive pad edges to electrically connect conductive pads 130 to one another and/or to locations off of stack 200. As will be appreciated by those skilled in the art, in this embodiment, side surface 210 of stack 200 (i.e., the side access layer) need not be planarized, nor need any material 170 be deposited on to that surface.

In another embodiment of the present invention, substrate 110 comprises a high impedance material such as, for example, silicon oxide, highly pure silicon, or ceramics. In this embodiment (not shown), after chip substrates 110 are selectively etched, the planarization process step illustrated in FIG. 7 may be performed directly on the edges 140 of chip substrates 10, without depositing any material 170 on side surface 210 of stack 200. In this manner, the above planarization step can provide a suitable access layer on which a side interconnect layer may be subsequently formed, without requiring any insulating material 170.

The above-described formation of a side access layer provides several advantages. Importantly, when initially securing semiconductor chips into a stack module, significant misalignment between chips is permitted without affecting subsequent formation of the side interconnect layer on a planarized side access surface. This avoids painstaking, time-consuming, and complex alignment processes commonly required in prior art methods. In addition, the manufacturing of chips 100 having a design and layout in accordance with the present invention may be carried out in integrated circuit or MEMS fabrication facilities using standard manufacturing techniques and processes. Furthermore, the above-described method of forming a side access and interconnect layer allows for a high degree of parallelism between the chips, which may be of particular importance in certain MEMS applications, such as the optical switches described in commonly assigned U.S. patent application Ser. No. 09/619,014 entitled “Switching Device and Method of Fabricating the Same”. As an additional benefit, chips in stack 200 may have a high density of conductive pads, e.g. 50 μm wide conductive pads 130 may be arranged on a chip with a pitch of about 100 μm. This permits side interconnect layer 250 to provide electrical connection for numerous signals on each chip in stack 200. Moreover, as indicated above, conductive pads 130 may also be formed near one or more edges of each chip 100 other than edge 140 in FIG. 1) to provide additional signal connections, and a further signal interconnect layer may then be formed, as described above, on another side surface of stack 200.

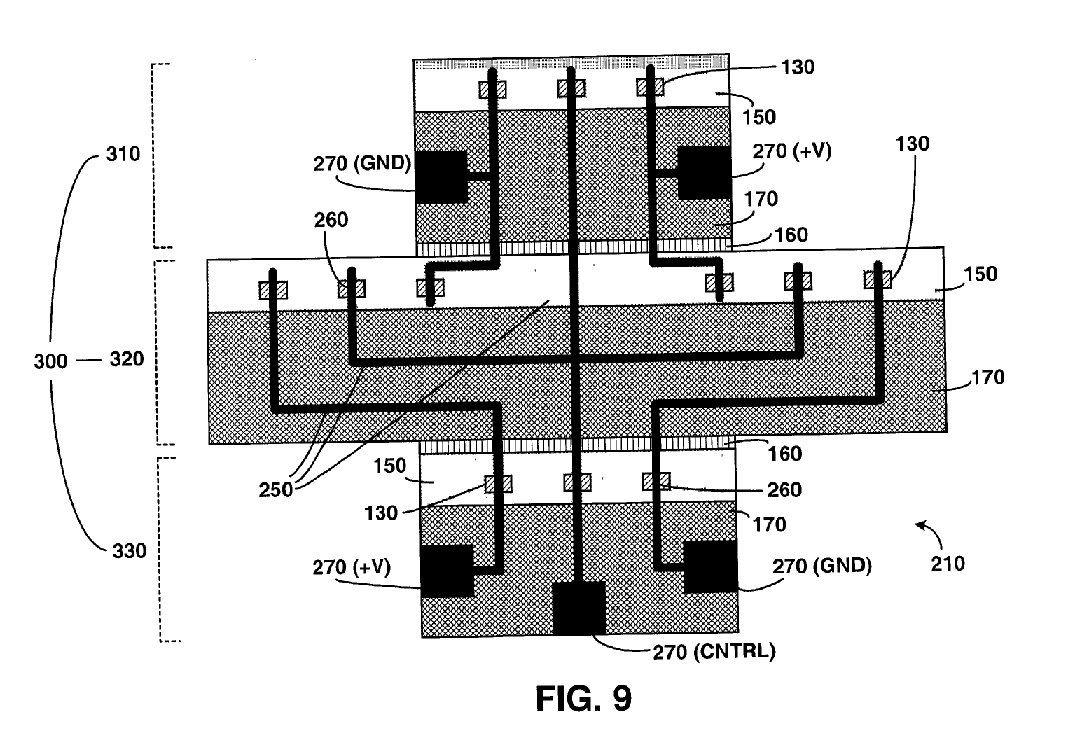

As an illustrative example, FIG. 9 shows the side access plane or surface 210 for an exemplary stack 300 of three semiconductor chip layers 310, 320, and 330 after undergoing processing in accordance with the preferred embodiment illustrated in FIGS. 3-8. Each of chips 310 and 330 contain a MEMS device having three polysilicon conductive pads 130 for connecting a positive voltage supply (V+) signal, a ground reference voltage signal (GND), and an input control voltage (CNTRL) to the respective chip 310 or 330. Chip 320 contains two MEMS devices and each of these devices also has three polysilicon conductive pads 130 for connecting to same signals. As shown in FIG. 9, side interconnect layer 250 connects each of the conductive pads 130, at a connect 260, to a side surface interconnect layer contact pad 270 corresponding to one of the V+, GND, or CNTRL voltage signals, as indicated. As will be appreciated, surface interconnect layer contact pads 270 may be connected by wire bonding to a circuit substrate (not shown) or stack 300 may be flip-chip oriented so that contact pads are positioned face down on corresponding contacts on the face of the circuit substrate. Also, as exemplified by the illustrative embodiment of FIG. 9, the semiconductor chips that form a stack need not be identical and may be of different sizes.

Alternatively, instead of forming a side access layer with interconnect 250, each exposed edge 135 of conductive pads 130 in FIG. 9 may be wire bonded either on or off the stack to provide a desired electrical connection. As described above, in this case surface 210 need not be planarized and material 170 is not required. As a further alternative, if the cross sectional area of conductive pad edges 135 are large enough, they may be directly flip-chip connected to corresponding contacts on the face of the circuit substrate.

While the invention has been described in conjunction with specific embodiments, it is evident that numerous alternatives, modifications, and variations will be apparent to those skilled in the art in light of the foregoing description.

What is claimed is:

1. A method of forming a side access layer on a semiconductor chip comprising:
forming a region of protective insulating material and one or more conductive pads above a major surface of a chip substrate, each conductive pad being located at least a certain height above the major surface of the substrate and at least a certain distance away from a side surface of the chip, the region of protective material generally extending between each conductive pad and the major surface of the substrate;
etching the chip substrate at the side surface to remove a portion of the chip substrate, wherein the protective insulating material protects each conductive pad during the etching of the chip substrate; and
exposing an edge of each conductive pad.

2. The method of claim 1 wherein exposing an edge of each conductive pad comprises planarizing the side surface of the chip to expose an edge of each conductive pad.

3. The method of claim 2 wherein planarizing the side surface of the chip comprises polishing the side surface of the chip.

4. The method of claim 3 wherein polishing the side surface of the chip includes performing chemical mechanical planarization.

5. The method of claim 3 wherein planarizing the side surface of the chip further comprises lapping the side surface of the chip.

6. The method of claim 2 further comprising forming a side interconnect layer on the side surface of the chip, the side interconnect layer providing an electrical connection to each conductive pad.

7. The method of claim 2 further comprising depositing a second insulating material on the side surface of the chip, prior to planarizing the side surface of the chip.

8. The method of claim 7 wherein the second insulating material is adhesive.

9. The method of claim 7 further comprising forming a side interconnect layer on the side surface of the chip, the side interconnect layer providing an electrical connection to each conductive pad.

10. The method of claim 9 wherein forming the side interconnect layer comprises forming a metallization layer.

11. The method of claim 10 wherein forming a metallization layer comprises forming a layer comprising titanium and aluminum.

12. The method of claim 1 further comprising bonding a wire to the edge of a conductive pad to provide an electrical connection.

13. The method of claim 1 wherein the region of protective material also generally extends between each conductive pad and the side surface of the chip.

14. The method of claim 1 wherein the region of protective material generally surrounds each conductive pad.

15. The method of claim 1 wherein the region of protective material extends along the entire major surface of the substrate.

16. The method of claim 15 further comprising planarizing a top surface of the region of protective material.

17. The method of claim 1 wherein the one or more conductive pads are not etch resistant.

18. The method of claim 17 wherein etching the chip substrate comprises chemically etching the chip substrate.

19. The method of claim 1 wherein the one or more conductive pads are formed of polysilicon material.

20. The method of claim 19 wherein the chip substrate comprises silicon.

21. The method of claim 20 wherein the protective insulating material is silicon oxide or silicon nitride.

22. The method of claim 21 wherein etching the chip substrate comprises chemically etching the chip substrate.

23. The method of claim 22 wherein chemically etching the chip substrate includes using KOH as an etchant.

24. The method of claim 22 wherein chemically etching the chip substrate includes using TMAH as an etchant.

25. The method of claim 1 wherein the semiconductor chip comprises one or more MEMS devices integrated with microelectronic circuitry.

26. The method of claim 1 further comprising, for each conductive pad, forming a conductive line running, at least in part, along the major surface of the substrate, the conductive line connecting that conductive pad to microelectronic circuitry in the chip.

27. The method of claim 1 wherein the protective insulating material is an oxide or nitride.

28. A semiconductor chip having a side access layer formed by the method of claim 17.

29. A semiconductor chip having a side access layer formed by the method of claim 15.

30. A semiconductor chip having a side access layer formed by the method of claim 1.

31. A method of forming a side access layer on a stack of semiconductor chips comprising:
for each chip to be included in the stack, forming a region of protective insulating material and one or more conductive pads above a major surface of a substrate of the chip, each of the conductive pads being located at least a certain height above the major surface of the chip substrate and at least a certain distance away from a side surface of the chip, the region of protective material generally extending between each conductive pad and the major surface of the substrate;
securing the chips in a stack so that the side surfaces of each of the chips are generally aligned with one another to provide a side stack surface;
etching the substrates of the chips at the side stack surface to remove a portion of each chip substrate, wherein the protective insulating material protects each conductive pad during the etching of the chip substrates; and
exposing an edge of the conductive pads on each chip.

32. The method of claim 31 wherein exposing an edge of the conductive pads on each chip comprises planarizing the side stack surface to expose an edge of the conductive pads on each chip.

33. The method of claim 32 wherein planarizing the side stack surface, after the etching of the chip substrates, comprises polishing the side stack surface.

34. The method of claim 33 wherein polishing the side stack surface includes performing chemical mechanical planarization.

35. The method of claim 33 wherein planarizing the side stack surface, after the etching of the chip substrates, further comprises lapping the side stack surface.

36. The method of claim 32 further comprising forming a side interconnect layer on the side stack surface, the side interconnect layer providing an electrical connection to the conductive pads on each chip.

37. The method of claim 32 further comprising depositing a second insulating material on the side stack surface, prior to planarizing the side stack surface.

38. The method of claim 37 wherein the second insulating material is adhesive.

39. The method of claim 37 further comprising forming a side interconnect layer on the side stack surface, the side interconnect layer providing an electrical connection to the conductive pads on each chip.

40. The method of claim 39 wherein forming the side interconnect layer comprises forming a metallization layer.

41. The method of claim 40 wherein forming a metallization layer comprises forming a layer comprising titanium and aluminum.

42. The method of claim 31 further comprising bonding a wire to the edge of a conductive pad on each chip to provide an electrical connection.

43. The method of claim 31 wherein, for each chip included in the stack, the region of protective material also generally extends between each conductive pad and the side surface of the chip.

44. The method of claim 31 wherein, for each chip included in the stack, the region of protective material surrounds each conductive pad.

45. The method of claim 31 wherein, for each chip included in the stack, the region of protective material generally extends along the entire major surface of the substrate.

46. The method of claim 45 further comprising, for each chip included in the stack, planarizing a top surface of the region of protective material.

47. The method of claim 31 wherein the chips in the stack are secured so that the side surfaces of each of the chips in the stack are aligned, the largest misalignment distance between the side surfaces of any two chips in the stack representing a maximum misalignment.

48. The method of claim 47 wherein securing the chips in a stack comprises bonding each chip to an adjacent chip.

49. The method of claim 48 wherein bonding each chip to an adjacent chip comprises applying a layer of adhesive material between the substrate of said chip and the layer of protective insulating material of the adjacent chip.

50. The method of claim 47 wherein the maximum misalignment is less than the minimum distance between each of the conductive pads on a chip and the side surface of that chip.

51. The method of claim 50 wherein each of the conductive pads on each chip is located the same distance away from the side surface of that chip.

52. The method of claim 31 further comprising, after securing the chips in a stack and before etching the substrates of the chips, initially planarizing the side stack surface, wherein after said initial planarizing, for each chip, each of the conductive pads remains at least some distance away from the side surface of that chip.

53. The method of claim 52 wherein initially planarizing the side stack surface comprises polishing the side stack surface.

54. The method of claim 53 wherein polishing the side stack surface includes performing chemical mechanical planarization.

55. The method of claim 52 wherein initially planarizing the side stack surface comprises grinding the side stack surface.

56. The method of claim 31 wherein the conductive pads are not etch resistant.

57. The method of claim 56 wherein etching the chip substrates comprises chemically etching the chip substrates.

58. The method of claim 31 wherein the conductive pads are formed of polysilicon material.

59. The method of claim 58 wherein each chip substrate comprises silicon.

60. The method of claim 59 wherein the protective insulating material is silicon oxide or silicon nitride.

61. The method of claim 60 wherein etching the chip substrates comprises chemically etching the chip substrates.

62. The method of claim 61 wherein chemically etching the chip substrates includes using KOH as an etchant.

63. The method of claim 61 wherein chemically etching the chip substrates includes using TMAH as an etchant.

64. The method of claim 31 wherein the each semiconductor chip comprises one or more MEMS devices integrated with microelectronic circuitry.

65. The method of claim 31 further comprising, for each conductive pad in each chip included in the stack, forming a conductive line running, at least in part, along the major surface of the substrate of that chip, the conductive line connecting that conductive pad to microelectronic circuitry in that chip.

66. The method of claim 31 wherein the protective insulating material is an oxide or nitride.

67. A stack of semiconductor chips having a side access layer formed by the method of claim 64.

68. A stack of semiconductor chips having a side access layer formed by the method of claim 60.

69. A stack of semiconductor chips having a side access layer formed by the method of claim 58.

70. A stack of semiconductor chips having a side access layer formed by the method of claim 31.
